(19) United States
(12) Patent Application Publication
(10) Pub. No.: US 2015/0015823 A1
(43) Pub. Date: Jan. 15, 2015

(54) LIQUID CRYSTAL PANEL AND MANUFACTURING METHOD THEREOF

(71) Applicant: SHENZHEN CHINA STAR OPTOELECTRONICS TECHNOLOGY CO., LTD., Shenzhen, Guangdong (CN)

(72) Inventors: Shih-Hsun Lo, Shenzhen (CN); Bing Han, Shenzhen (CN)

(21) Appl. No.: 14/240,365

(22) PCT Filed: Jan. 28, 2014
(86) PCT No.: PCT/CN2014/071707

§ 371 Date: Feb. 22, 2014

(30) Foreign Application Priority Data
Jul. 9, 2013 (CN) 201310286733.1

(51) Int. Cl. G02F 1/1368; H01L 27/12; H01L 21/66; G02F 1/1365; G02F 1/1335

(52) U.S. Cl. CPC G02F 1/1368; G02F 1/1365; G02F 1/133514; G02F 1/133516; H01L 22/30; H01L 27/1259; G02F 2001/136254
USPC 349/43; 438/29

(57) ABSTRACT

The present invention provides a liquid crystal panel and a method for manufacturing the same. The liquid crystal panel comprises a color filter substrate including a first testing point of a common electrode thereon; and a thin film transistor substrate including a second testing point thereon for testing circuits of the color filter substrate, and a switching unit is arranged between the second testing point and the first testing point, and enables the circuit connection between the second testing point and the first testing point to be in a disconnected state when the potential of the second testing point is abnormal. In this manner, the potential of the first testing point inside the color filter substrate may be prevented from interfere as well as a phenomenon of picture display abnormality of the liquid crystal panel due to short in the testing points.

### FIELD OF THE INVENTION

The present disclosure relates to manufacturing process for a liquid crystal panel, and particularly, to a liquid crystal panel and a manufacturing method thereof.

### BACKGROUND OF THE INVENTION

In the production process of a thin film transistor-liquid crystal display (TFT-LCD) panel, the yield rate of the liquid crystal panel must be monitored through a session of test, such as light-on test.

As shown in FIG. 1, to facilitate testing, a thin film transistor substrate 10 of the liquid crystal panel is provided with peripheral test circuits 11 connected with circuits to be tested on a display area 20 and a color filter substrate 30. During the light-on test, a cell tester shorting bar 12 is generally arranged on the thin film transistor substrate to divide the circuits to be tested into several groups of odd circuit lines and even circuit lines. Then odd circuit lines and even circuit lines are electrically connected with external light-on test equipment (not shown in this figure) through their corresponding testing points (such as odd data line testing points 13 and even data line testing points 14 shown in FIG. 1) to complete the test task. After the test is completed, the connections between the above-mentioned peripheral test circuits 11 with the circuits on the display area 20 and with the color filter substrate 30 generally need to be removed or laser cut, such that the test circuits can restore to respective independent states before the test.

Generally, this removal or cut operation is relatively simple for data lines and gate lines of the display area, but relatively difficult for common electrode on the color filter substrate. As shown in FIG. 1, the above-mentioned objective may be fulfilled by performing laser cut at A-A′ on the connection between the cell tester shorting bar 12 and display area circuits led out from fanout area 21. However, the connection between a CF COM transfer pad 31 (hereafter, referred to as first testing point) of the common electrode on the color filter substrate 30 and a CF COM pad 15 (hereafter, referred to as second testing point) on the thin film transistor substrate 10 cannot be removed or cut due to a long distance relative to a laser cut area or the space limitation of leads.

Generally, such connection does not cause any problems. However, during the mounting of a conductive front frame on the liquid crystal display module group, if the conductive front frame 40 is pressed firmly, the conductive front frame 40 is caused to be deformed to form contact shorting with the second testing point 15 on the thin film transistor substrate 10 (as shown in FIGS. 2A and 2B). At this moment, a phenomenon of picture abnormity, such as picture noise and flicker, is caused. This is mainly because that the conductive front frame 40 is generally in a ground potential; and when the conductive front frame 40 is deformed to contact the second testing point 15, the potential of the first testing point 31 of the common electrode on the color filter substrate 30, still in connection with the second testing point 15, is abnormal such that the ground potential of the whole liquid crystal panel is abnormal, and thus a basis reference of digital signals of a driver circuit is interfered thereby to present a fault of picture abnormity.

### SUMMARY OF THE INVENTION

With respect to the above-mentioned problems, the present disclosure provides a liquid crystal panel and a manufacturing method thereof.

The present disclosure provides a liquid crystal panel, comprising: a color filter substrate, including a first testing point of a common electrode thereon; and a thin film transistor substrate, including a second testing point thereon for testing circuits of the color filter substrate, wherein a switching unit is arranged between the second testing point and the first testing point, and enables the circuit connection between the second testing point and the first testing point to be in a disconnected state when the potential of the second testing point is abnormal.

In a preferred implementation, the switching unit is also used for implementing the circuit connection between the second testing point and the first testing point during light-on test.

According to embodiment 1 of the present disclosure, in above implementation, the switching unit may be a thin film transistor switch, of which the drain is connected to the second testing point, the source is connected to the first testing point, and the gate is used as a control end to receive a control voltage for controlling the turn-on or turn-off of the thin film transistor switch.

Further, in above implementation, a switch testing point connected to the control end of the thin film transistor switch is also arranged on the thin film transistor substrate and used for applying the control voltage for controlling the turn-on or turn-off of the thin film transistor switch.

According to embodiment 2 of the present disclosure, in a preferred implementation, the switching unit may be a switching diode, the anode of the switching diode is connected to the second testing point, and the cathode of the switching diode is connected to the first testing point.

According to embodiment 3 of the present disclosure, in a preferred implementation, the switching unit may be two or more parallel switching diodes, the anodes of the switching diodes are connected in parallel to the second testing point, and the cathodes of the switching diodes are connected in parallel to the first testing point.

According to embodiment 4 of the present disclosure, in a preferred implementation, the switching unit may be two or more series switching diodes, the anodes of the switching diodes are serially connected to the second testing point, and the cathodes of the switching diodes are serially connected to the first testing point.

In above implementation, the switching unit is preferably arranged on the thin film transistor substrate.

The present disclosure also provides a manufacturing method of a liquid crystal panel, including the steps of: manufacturing a color filter substrate including a first testing point of a common electrode thereon; manufacturing a thin film transistor substrate including a second testing point for testing circuits of the color filter substrate; and disposing a switching unit between the second testing point and the first testing point, which enables the circuit connection between the second testing point and the first testing point to be in a disconnected state when the potential of the second testing point is abnormal.

Further, the switching unit is used to connect the circuit connection between the second testing point and the first testing point during light-on test.

According to embodiment 1 of the present disclosure, the switching unit described above may use a thin film transistor switch, of which the drain is connected to the second testing point, the source is connected to the first testing point, and the gate is used as a control end to receive a control voltage for controlling the turn-on or turn-off of the thin film transistor switch.

Further, a switch testing point connected to the control end of the thin film transistor switch is also arranged on the thin film transistor substrate described above and is used for applying the control voltage for controlling the turn-on or turn-off of the thin film transistor switch.

According to embodiment 2 of the present disclosure, the switching unit described above may use one switching diode, the anode of the switching diode is connected to the second testing point, and the cathode of the switching diode is connected to the first testing point.

According to embodiment 3 of the present disclosure, the switching unit described above may use two or more switching diodes in parallel, the anodes of the switching diodes are connected in parallel to the second testing point, and the cathodes of the switching diodes are connected in parallel to the first testing point.

According to embodiment 4 of the present disclosure, the switching unit described above may use two or more series switching diodes, the anodes of the switching diodes are serially connected to the second testing point, and the cathodes of the switching diodes are serially connected to the first testing point.

According to the present disclosure, the switching unit is added in the circuit connection between the first testing point of the common electrode of the existing color filter substrate and the second testing point of the thin film transistor substrate for testing the circuit of the color filter substrate, so as to disconnect the circuit connection between the two testing points when the potential of the second testing point is abnormal, for example, when the condition of the potential with zero is happened to the second testing point due to contact shorting between the second testing point with a conductive outer frame, such that the potential of the first testing point inside the color filter substrate may be prevented from interfere as well as a phenomenon of picture display abnormality of the liquid crystal panel due to short in the testing points. Other features and advantages of the present disclosure will be illustrated in the following description, and are partially obvious based on the description or understood through implementing the present disclosure.

### BRIEF DESCRIPTION OF THE DRAWINGS

FIG. 1 is a schematic diagram of circuit connection between a liquid crystal panel and peripheral test circuits in the prior art;

FIG. 2A is a local schematic diagram of an assemble of liquid crystal panel in the prior art;

FIG. 2B is a local schematic diagram of contact shorting of a conductive front frame with a testing point due to its pressing deformation;

FIG. 3 is a schematic diagram of circuit connection of a switching unit in embodiment 1 of the present disclosure;

FIG. 4 is a schematic diagram of circuit connection of a switching unit in embodiment 2 of the present disclosure;

FIG. 5 is a schematic diagram of circuit connection of a switching unit in embodiment 3 of the present disclosure;

FIG. 6 is a schematic diagram of circuit connection of a switching unit in embodiment 4 of the present disclosure;

FIG. 7 is a schematic diagram of comparison between threshold voltages in embodiment 3 and embodiment 4 of the present disclosure;

FIG. 8 is a schematic diagram of a thin film transistor equivalent to a switching diode in the present disclosure.

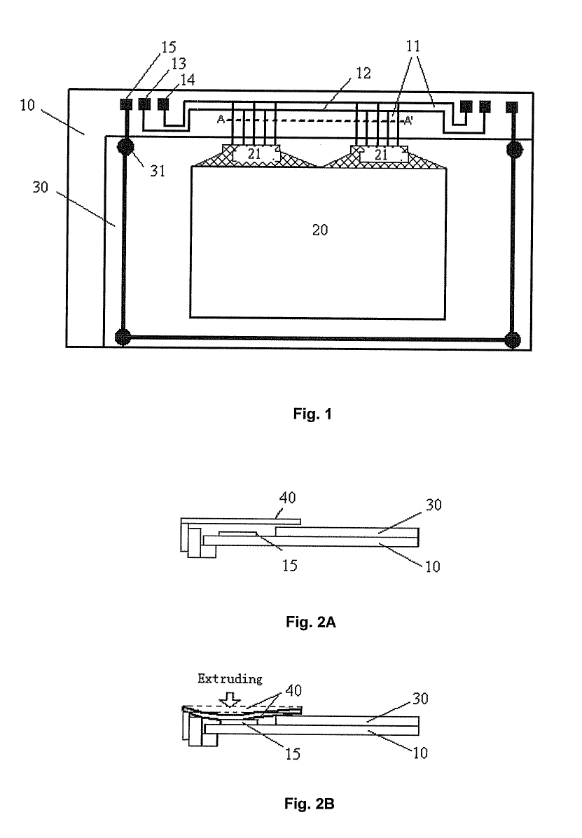

### DETAILED DESCRIPTION OF THE EMBODIMENTS

To prevent a fault of picture abnormity due to contact shorting with a testing point on a thin film transistor substrate caused by deformation of a conductive front frame, a liquid crystal panel and a manufacturing method thereof in the prior art will be further improved in the present disclosure. That is, a switching unit 16 is added into circuit connection between a second testing point 15 on an existing thin film transistor substrate 10 and a first testing point 31 on a color filter substrate 30, such that the circuit connection between the second testing point 15 and the first testing point 31 is disconnected when the potential of the second testing point 15 is abnormal.

With reference to the accompanying drawings, the objectives, technical solutions and achieved technical effects of the present disclosure will be described in detail below in conjunction with the non-limiting embodiments.

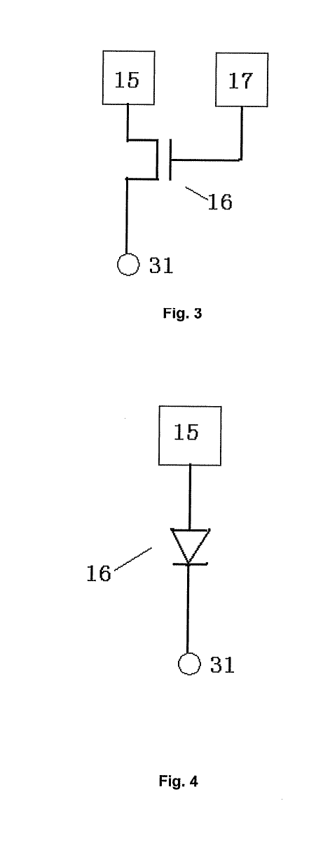

FIG. 3 shows a specific implementation scheme of embodiment 1 of the present disclosure. In this case, the switching unit 16 adopts one thin film transistor switch, of which the drain is connected to the second testing point 15, the source is connected to the first testing point 31 and the gate is used as a control end receiving a control voltage for controlling the on or off states of the thin film transistor switch. Further, the gate may be connected to a switch testing point 17 also arranged on the thin film transistor substrate 10. During the light-on test, a control voltage sufficient for turning on the drain and the source of the thin film transistor switch may be applied to the switch testing point 17 via a probe, such that the circuit connection between the second testing point 15 and the first testing point 31 is in a connected state and the test voltage on the second testing point 15 is thereby transferred inside of the color filter substrate 30, thus realizing a test function for circuits inside the color filter substrate 30. In a normal state, because no voltage is on the switch testing point 17, there is no conduction path between the drain and the source of the thin film transistor switch, and correspondingly, the circuit connection between the second testing point 15 and the first testing point 31 is in a disconnected state. Thus, even if an abnormal condition of a potential with zero was happened to the second testing point 15 due to contact shorting with the conductive outer frame 40, the potential of the first testing point 31 of the common electrode on the color filter substrate 30 would not be affected, and thus the objective of preventing picture abnormity due to short of the testing points is fulfilled. This on-off manner has strong controllability and high flexibility. Besides the light-on test, the circuit connection between the second testing point 15 and the first testing point 31 may also be switched from the disconnected state to the connected state, when there is other demand, by applying the control voltage to the switch testing point 17. The same technical effect may also be achieved by adopting an NMOS transistor switch besides the above-mentioned thin film transistor switch, which is not described in detail herein.

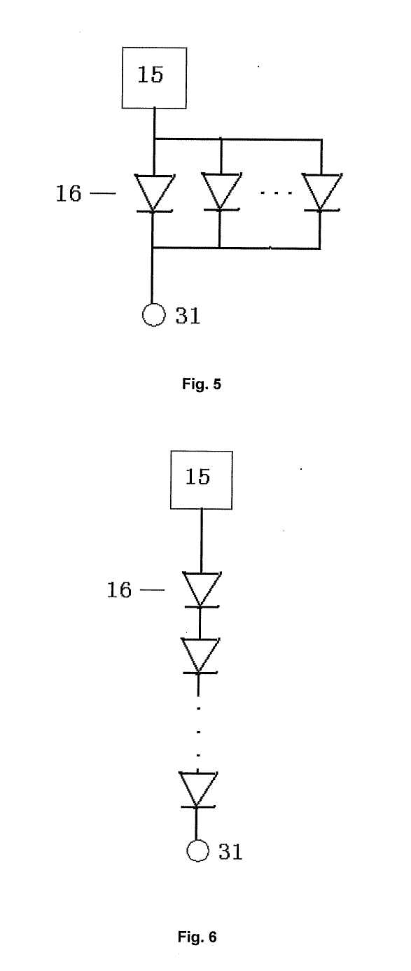

FIG. 4 shows a specific implementation scheme of embodiment 2 of the present disclosure. In this case, the switching unit 16 adopts a switching diode, of which the anode is connected to the second testing point 15 and the cathode is connected to the first testing point 31. During the light-on test, a test voltage greater than a threshold voltage of the switching diode is applied to the second testing point 15, and the switching diode is switched from a turn-off state to a turn-on state, such that the test voltage is transferred inside of the color filter substrate 30, thus realizing a test function for circuits in the color filter substrate 30. In a normal state, because no voltage exists on the second testing point 15, the switching diode is in the turn-off state, and correspondingly, the circuit connection between the second testing point 15 and the first testing point 31 is in a disconnected state. Thus, even if an abnormal condition of a potential with zero was happened to the second testing point 15 due to contact shorting with the conductive outer frame 40, the potential of the first testing point 31 would not be affected, such that the objective of preventing picture abnormity due to shorting of the testing points is fulfilled.

FIG. 5 shows embodiment 3 of the present disclosure, which performs further exploration based on embodiment 2. In this case, the switching unit 16 adopts two or more parallel switching diodes, the anodes of all the switching diodes are connected in parallel to the second testing point 15, and the cathodes are connected in parallel to the first testing point 31. In this embodiment, the magnitudes of the threshold voltages of the switching diodes for switching the circuit connection between the second testing point 15 and the first testing point 31 from a disconnected state to a connected state are not varied and it is still the same as one switching diode case in embodiment 2. However, when the two testing points are connected, the current flowing from the second testing point 15 to the first testing point 31 may increase, thus it can be more quickly to realize effect of voltage stabilization.

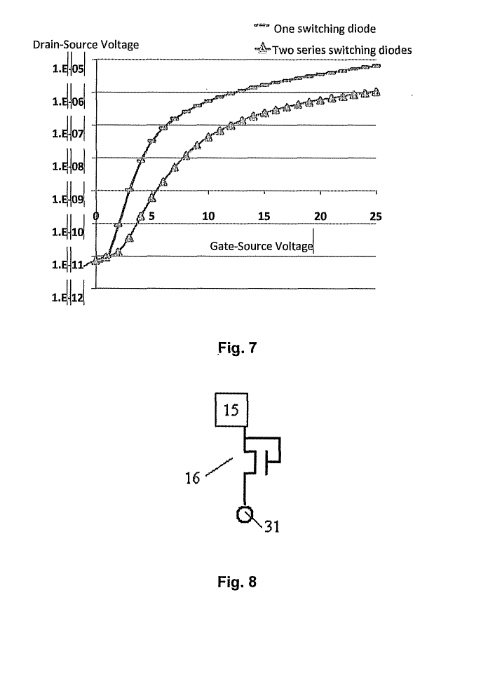

In the above-mentioned embodiment, since the threshold voltage for one switching diode from the turn-off state to the turn-on state is relative low and low as 0.7V sometimes, the outcome of preventing picture abnormity caused by shorting of the testing points is not quite ideal. Therefore, the present disclosure proposes a new technical solution in embodiment 4, as shown in FIG. 6. The switching unit 16 adopts two or more series switching diodes. With increase of the number of the switching diodes, the threshold voltage enabling the circuit connection between the second testing point 15 and the first testing point 31 to switch from the disconnected state to the connected state is also increased. As shown in FIG. 7, when one switching diode is used, the threshold voltage is about 3V, and when two series switching diodes are used, the threshold voltage is improved to about 5V. The principle of realizing a fault prevention function by using a plurality of series switching diodes as the switching unit is basically the same as that of the previous several embodiments, which is not described further herein.

Although the present disclosure has been described with reference to the preferred embodiments, various modifications could be made to the present disclosure without departing from the scope of the present disclosure and components in the present disclosure could be substituted by equivalents. For example, a function being the same as said switching diode is realized by using a thin film transistor as shown in FIG. 8 with the gate and the drain short-circuited, where portion between the drain and the source is equivalent to said switching diode. Therefore, the present disclosure is not limited to the specific embodiments disclosed in the description, but includes all technical solutions falling into the scope of the claims, and equivalent variations and improvements based on the technical solutions of the present disclosure should not be excluded out of the protection scope of the present disclosure.

What is claimed is:

1. A liquid crystal panel, comprising:
a color filter substrate, including a first testing point of a common electrode thereon;
a thin film transistor substrate, including a second testing point thereon for testing circuits of the color filter substrate;
wherein a switching unit is arranged between the second testing point and the first testing point, and enables the circuit connection between the second testing point and the first testing point to be in a disconnected state when the potential of the second testing point is abnormal.

2. The liquid crystal panel of claim 1, wherein:
the switching unit is used for implementing the circuit connection between the second testing point and the first testing point during light-on test.

3. The liquid crystal panel of claim 1, wherein:
the switching unit is a thin film transistor switch, of which the drain is connected to the second testing point, the source is connected to the first testing point, and the gate is used as a control end to receive a control voltage for controlling the turn-on or turn-off of the thin film transistor switch.

4. The liquid crystal panel of claim 2, wherein:
the switching unit is a thin film transistor switch, of which the drain is connected to the second testing point, the source is connected to the first testing point, and the gate is used as a control end to receive a control voltage for controlling the turn-on or turn-off of the thin film transistor switch.

5. The liquid crystal panel of claim 3, wherein:
a switch testing point connected to the control end of the thin film transistor switch is arranged on the thin film transistor substrate and used for applying the control voltage for controlling the turn-on or turn-off of the thin film transistor switch.

6. The liquid crystal panel of claim 4, wherein:
a switch testing point connected to the control end of the thin film transistor switch is arranged on the thin film transistor substrate and used for applying the control voltage for controlling the turn-on or turn-off of the thin film transistor switch.

7. The liquid crystal panel of claim 1, wherein:
the switching unit is a switching diode, the anode of the switching diode is connected to the second testing point, and the cathode of the switching diode is connected to the first testing point.

8. The liquid crystal panel of claim 2, wherein:
the switching unit is a switching diode, the anode of the switching diode is connected to the second testing point, and the cathode of the switching diode is connected to the first testing point.

9. The liquid crystal panel of claim 1, wherein:
the switching unit is two or more switching diodes in parallel, the anodes of the switching diodes are connected in parallel to the second testing point, and the cathodes of the switching diodes are connected in parallel to the first testing point.

10. The liquid crystal panel of claim 2, wherein:
the switching unit is two or more switching diodes in parallel, the anodes of the switching diodes are connected in parallel to the second testing point, and the cathodes of the switching diodes are connected in parallel to the first testing point.

11. The liquid crystal panel of claim 1, wherein:
the switching unit is two or more series switching diodes, the anodes of the switching diodes are serially connected to the second testing point, and the cathodes of the switching diodes are serially connected to the first testing point.

12. The liquid crystal panel of claim 2, wherein:
the switching unit is two or more series switching diodes, the anodes of the switching diodes are serially connected to the second testing point, and the cathodes of the switching diodes are serially connected to the first testing point.

13. The liquid crystal panel of claim 1, wherein:
the switching unit is arranged on the thin film transistor substrate.

14. A method for manufacturing a liquid crystal panel, including the steps of:
manufacturing a color filter substrate including a first testing point of a common electrode thereon;
manufacturing a thin film transistor substrate including a second testing point thereon for testing circuits of the color filter substrate; and
disposing a switching unit between the second testing point and the first testing point, which enables the circuit connection between the second testing point and the first testing point to be in a disconnected state when the potential of the second testing point is abnormal.

15. The method of claim 14, wherein:
the switching unit is used to connect the circuit connection between the second testing point and the first testing point during light-on test.

16. The method of claim 14, wherein:
the switching unit uses a thin film transistor switch, of which the drain is connected to the second testing point, the source is connected to the first testing point, and the gate is used as a control end to receive a control voltage for controlling the turn-on or turn-off of the thin film transistor switch.

17. The method of claim 16, wherein:
a switch testing point connected to the control end of the thin film transistor switch is arranged on the thin film transistor substrate and is used for applying the control voltage for controlling the turn-on or turn-off of the thin film transistor switch.

18. The method of claim 14, wherein:
the switching unit uses one switching diode, the anode of the switching diode is connected to the second testing point, and the cathode of the switching diode is connected to the first testing point.

19. The method of claim 14, wherein:
the switching unit uses two or more switching diodes in parallel, the anodes of the switching diodes are connected in parallel to the second testing point, and the cathodes of the switching diodes are connected in parallel to the first testing point.

20. The method of claim 14, wherein:
the switching unit uses two or more series switching diodes, the anodes of the switching diodes are serially connected to the second testing point, and the cathodes of the switching diodes are serially connected to the first testing point.
